(19) United States
(12) Patent Application Publication
(10) Pub. No.: US 2010/0326599 A1
(43) Pub. Date: Dec. 30, 2010

(54) INTEGRATED APPARATUS FOR VACUUM PRODUCING

(76) Inventors: Tae-Kyong Hwang, Gyeonggi-do (KR); Heaung-Shig Oh, Gyeonggi-do (KR); Myung-Keun Noh, Seoul (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/600,655

(22) PCT Filed: May 16, 2008
(86) PCT No.: PCT/KR08/02757

§ 371 Date: May 10, 2010

(30) Foreign Application Priority Data
May 17, 2007 (KR) 10- 2007 -0048240

(51) Int. Cl. H01L 21/306

(52) U.S. Cl. 156/345.29

(57) ABSTRACT

Disclosed is an integrated vacuum producing apparatus, which vacuumizes a process chamber of an apparatus for manufacturing semiconductors, flat panel displays, etc. or exhausts gaseous material and by-products generated within the process chamber to an outside so as to purify it. Gaseous material, e.g. gas, generated within a chamber for manufacturing a semiconductor, a flat panel display, etc. is exhausted through each separate exhaust line so as to be purified. Therefore, excessive operation of a purifying system can be prevented through distribution of exhaust gas so that life span can be extended according to the operation of the apparatus. Also, exhausting can be smoothly achieved through each exhaust line so that it is possible to prevent delay of a semi-conductor manufacturing process due to inability of exhausting, and to easily remove non-reacted gas and by-products in an exhausting process.

### TECHNICAL FIELD

The present invention relates to an integrated vacuum producing apparatus, and more particularly to an integrated vacuum producing apparatus, which can vacuumize the interior of a chamber, exhaust gaseous material, e.g. gas generated within the chamber, through each separate exhaust line so as to purify it, and remove non-reacted gas and by-products contained in the gas in a process of manufacturing semiconductors, flat panel displays, etc.

### BACKGROUND ART

In general, a semiconductor manufacturing process includes a fabrication process and an assembly process. The fabrication process means a process for manufacturing what are called semiconductor chips in such a manner that a thin film is deposited on each wafer within various kinds of processor chambers, and a step of selectively etching the deposited thin film is repetitively performed so as to form a specific pattern. The assembly process means a process for manufacturing a finished product in such a manner that the semiconductor chips manufactured in the above-described fabrication process are separated from each other and are assembled with a lead frame.

At this time, the process for depositing a thin film on the above-described wafer or etching a deposited thin film on a wafer is performed within the process chamber at a high temperature by using noxious gas, such as silane, arsine, boron chloride, etc., and process gas, such as hydrogen gas. Also, during the above-described process, various kinds of gases having flammability, corrosive alien substance, toxic gas containing inducing elements, etc. are generated in a large amount within the process chamber.

Therefore, a semiconductor manufacturing apparatus includes one vacuum system, in which a scrubber, which purifies exhaust gas discharged from the process chamber and discharges the exhaust gas to the atmosphere, is formed at a rear end of a vacuum pump forming the process chamber into a vacuum condition.

In a conventional vacuum system, at least one vacuum pump apparatus, in which a Booster pump and a low vacuum pump are included so as to exhaust gaseous material, e.g. gas, generated within the chamber, and are connected with the chamber trough a first exhaust pipe, respectively, is included in the interior of the main body. Also, a scrubber for purifying gas exhausted from the vacuum pump apparatus is separately included in the exterior of the main body, and the vacuum pump apparatus and the scrubber are connected with each other through a second exhaust pipe longitudinally extended.

In such a conventional vacuum system, gas, which is generated in a process of manufacturing semiconductors and flat panel displays according to each operation of the vacuum pump apparatus, is purified by sequentially passing through the first exhaust pipe, the vacuum pumping apparatus, and the second exhaust pipe so as to pass through a scrubber, and is exhausted outside.

However, the above-described vacuum system requires a large installation area for installing a main body having the vacuum pump apparatus and the scrubber. Therefore, it has been required to improve effectiveness in using it.

Recently, in order to satisfy such a requirement, “modulated gas vacuum purifier” was disclosed in Korea Utility Model NO. 0374862.

As shown in FIG. 4, such a vacuum purifier 100 includes a vacuum producing apparatus and a scrubber within a main body thereof so that gas generated within a chamber is exhausted by the vacuum producing apparatus, and the gas exhausted from the vacuum producing apparatus is purified through the scrubber so as to be exhausted outside.

The above-described vacuum purifier reduces the installing area in such a manner that it includes the vacuum producing apparatus and the scrubber with the main body. However, the vacuum purifier has a structure where the gas exhausted from the vacuum producing apparatus is piled at the scrubber so as to be purified. Therefore, there is a disadvantage in that, in a case where the scrubber has trouble, operation of the vacuum purifier is stopped so that a process for manufacturing semiconductors is delayed.

### DISCLOSURE OF INVENTION

### Technical Problem

Therefore, the present invention has been made in view of the above-mentioned problems, and it is an object of the present invention to provide an integrated vacuum producing apparatus which can exhaust gaseous material, e.g. gas, generated within a chamber in a process for manufacturing semiconductors, a flat panel displays, etc. through each separate exhaust line so as to purify it, remove non-reacted gas and by-products contained in the gas during the exhausting process, and reduce the installing area for equipment constituting the vacuum producing apparatus.

### Technical Solution

According to an aspect of the present invention, there is provided an integrated vacuum producing apparatus, which vacuumizes a process chamber of an apparatus for manufacturing semiconductors, flat panel displays, etc., or exhausts gaseous material and by-products generated within the process chamber to an outside so as to purify them, the integrated vacuum producing apparatus including: a main body; at least one vacuum pump apparatus received within the main body, the vacuum pump apparatus including a low vacuum pump so as to vacuumize the chamber or exhaust gaseous material and by-products generated within the chamber to an outside, the vacuum pump apparatus being connected with the chamber through a first exhaust pipe; at least one scrubber connected with the vacuum pump apparatus through a second exhaust pipe, the scrubber being received within the main body so as to purify the gaseous material; at least one trap connected with the vacuum pump apparatus, the trap causing additional chemical reaction respective to non-reacting gas and by-products contained in gaseous material in the chamber, which flows into the low vacuum pump and the scrubber, so as not to allow them from flowing into the low vacuum pump and the scrubber so that an average time interval between trouble occurrences in the low vacuum apparatus and the scrubber is extended; and a controller connected with the vacuum pump apparatus, the scrubber, and the trap so as to integrally control them.

Also, an exterior of the main body is surrounded by a case.

According to another aspect of the present invention, there is provided an integrated vacuum producing apparatus, which vacuumizes a process chamber of an apparatus for manufacturing semiconductors, flat panel displays, etc. or exhausts gaseous material and by-products generated within the process chamber to an outside so as to be purified, the integrated vacuum producing apparatus including: a main body; and at least one vacuum unit which is included in an interior of the main body while corresponding to the chamber and includes a vacuum pump apparatus, a scrubber, and a trap, the vacuum pump apparatus being received within the main body, including a low vacuum pump so as to vacuumize the chamber or exhaust gaseous material and by-products generated within the chamber to an outside, and being connected with the chamber through a first exhaust pipe, the scrubber being connected with the vacuum pump apparatus through a second exhaust pipe so as to purify gaseous material exhausted from the vacuum pump apparatus, the trap being connected with the vacuum pump apparatus, and inducing additional chemical reaction respective to non-reacted gas and by-products contained in the gaseous material in the chamber, which flow into the low vacuum pump and the scrubber, so that the trap prevents them from flowing into the low vacuum pump and the scrubber so as to extend an average time interval between trouble occurrences in the low vacuum apparatus and the scrubber.

Also, the integrated vacuum producing apparatus includes a controller for integrally control the vacuum unit.

Also, the vacuum unit is surrounded by a case so as to be modulized.

Also, the vacuum pump apparatus further includes a booster pump for increasing an exhausting speed of the low vacuum pump.

Also, the trap is connected with a front end of the booster pump.

Also, the trap is connected between the booster pump and the low vacuum pump.

Also, the trap is connected between a front end of the booster pump, the booster pump, and the low vacuum pump.

### ADVANTAGEOUS EFFECTS

Such an integrated vacuum producing apparatus according to the present invention exhausts gaseous material, e.g. gas, generated within a chamber for manufacturing semiconductors, flat panel displays, etc. through each separate exhaust line so as to purify it. Therefore, excessive operations of a purifying system can be prevented through distribution of exhaust gas so that life span of the apparatus can be extended according to the operation of the apparatus. Also, the exhaust operation can be smoothly achieved through each exhaust line so that it is possible to prevent delay of a semiconductor manufacturing process due to inability in exhausting, and to easily remove non-reacted gas and by-products in an exhausting process. In addition, the integrated vacuum producing apparatus integrally includes the purifying system within the apparatus, thereby reducing installing area.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is a perspective view of an integrated vacuum producing apparatus according to an exemplary embodiment of the present invention;

FIG. 2 is a side view of the integrated vacuum producing apparatus shown in FIG. 1;

FIG. 3 is a view illustrating a controller for controlling a vacuum unit shown in FIG. 1; and

FIG. 4 is a side view of a conventional vacuum system.

### MODE FOR THE INVENTION

Hereinafter, an integrated vacuum producing apparatus according to an exemplary embodiment of the present invention will be described in detail with reference to the accompanying drawings.

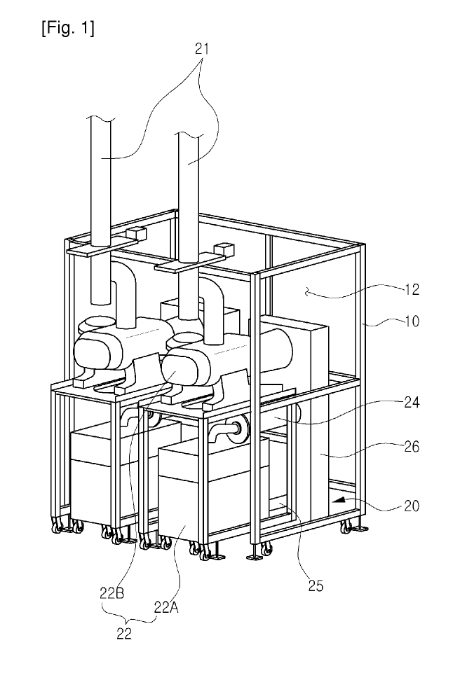

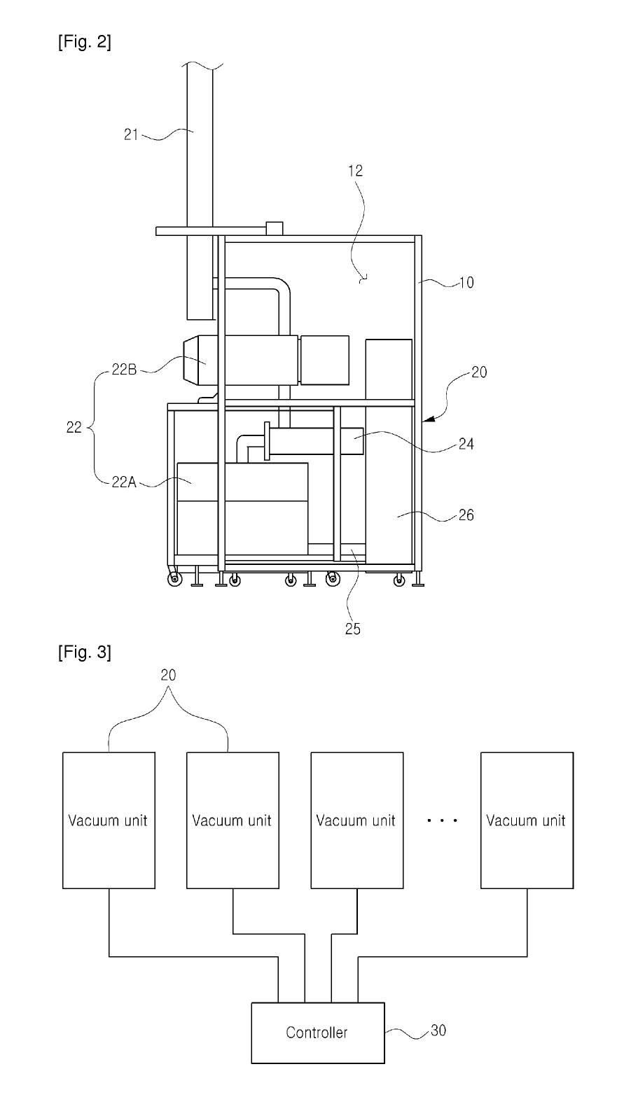

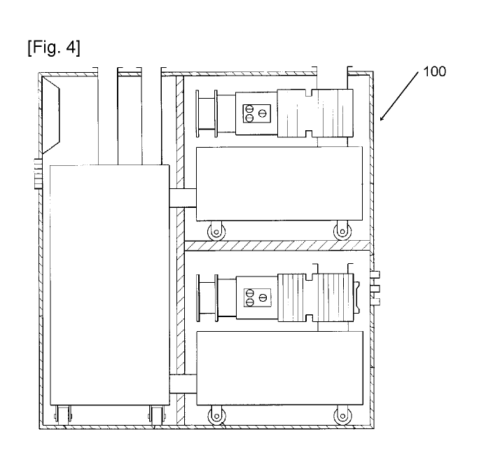

As shown in FIGS. 1 and 2, an integrated vacuum producing apparatus according to an exemplary embodiment of the present invention includes a main body 10 having a predetermined frame and at least one vacuum unit 20 included in the main body 10, the vacuum unit exhausting and purifying gaseous material and by-products, which are generated within a chamber (not shown) of an apparatus for manufacturing a semi-conductor, a flat panel display, etc. through each separate exhaust line.

The main body 10 is formed by a predetermined frame, and a receiving space 12 is formed in the interior of the main body. A separate case (not shown) surrounds the exterior of this main body 10.

The vacuum unit 20 is included in the receiving space 12 of the main body 10 while corresponding to the chamber so as to exhaust gaseous material, e.g. gas, generated in the chamber through each separate exhaust line and purify it. In order to achieve this, the vacuum unit 20 includes a vacuum pump apparatus 22, a trap 24 connected to the vacuum pump apparatus 22 so as to remove non-reacted gas and by-products contained in the gas exhausted from the chamber, and a scrubber 26 connected to the vacuum pump apparatus 22 so as to purify the gas exhausted from the vacuum pump apparatus 22.

The vacuum pump apparatus 22 for exhausting gas generated within the chamber is connected with the chamber through a first exhaust pipe 21.

Such vacuum pump apparatus 22A includes low vacuum pump 22A for exhausting gas generated within the chamber. Also, the vacuum pump apparatus 22A further includes a booster pump 22B so as to smoothly exhaust gas generated within the chamber. At this time, the booster pump 22B increases the exhaust speed of the low vacuum pump 22A.

The trap 24 causes an additional chemical reaction respective to non-reacted gas and by-products, which are contained in gas exhausted within the chamber, so as to prevent them from flowing into the low vacuum pump 22A and the scrubber 26, so that the average time interval between trouble occurrences in the low vacuum pump 22A and the scrubber 26 can be longer. At least one trap is connected with the vacuum pump apparatus 22. At this time, the trap 24 can be connected to the front end of the booster pump 22B or between the booster pump 22B and the low vacuum pump 22A. Also, the trap 24 can be connected between the front end of the booster pump 22B, the booster pump 22B, and the low vacuum pump 22A.

In the present embodiment, it is illustrated that the trap 24 is connected between the booster pump 22B and low vacuum pump 22A. In addition, in order to prevent non-reacted gas and by-products discharged from the chamber from flowing into the low vacuum pump 22A and scrubber 26, the trap 24 can be included at various positions of the exhaust line.

Herein, the trap 24 for preventing non-reacted gas and by-products contained in gas exhausted from the chamber from flowing into the low vacuum pump 22A and the scrubber 26 is a known technique. Therefore, those skilled in the art can easily operate the trap 24. Therefore, detailed description of the trap will be omitted.

The scrubber 26 performs a function of purifying gas exhausted from the vacuum pump apparatus 22 and is connected with the vacuum pump apparatus 22 through the second exhaust pipe 25. Such a technique where gas is purified through the scrubber 26 is a known technique. Therefore, the detailed description of the structure of the scrubber 26 will be omitted.

Also, as shown in FIG. 3, the vacuum producing apparatus according to the present invention further includes a controller 30 for integrally controlling each vacuum unit 20 included in the main body 10 while corresponding to the chamber so as to make each separate exhaust line. The controller 30 is connected with each vacuum unit 20, and integrally controls each vacuum unit 20 according to pre-input information.

Although not shown, it is possible that the above-described controller 30 is connected with the vacuum pump apparatus 22, the trap 24, and the scrubber 26 so as to integrally control them according to pre-input information.

Also, each vacuum unit 20 is included within the main body 10 in such a manner that it is covered by a separate case (not shown) so as to be modulized. Due to this structure, it is possible to easily replace each vacuum unit 20 when it has trouble.

The operation of the integrated vacuum purifier, which has a structure described above, according to an exemplary embodiment of the present invention, will be described below.

In a case where, by using the integrated vacuum producing apparatus according to an exemplary embodiment of the present invention, it is intended that a chamber of an apparatus for manufacturing a semiconductor, a flat pannel display, etc., is vacuumized or gaseous material generated in the chamber, i.e. gas is exhausted to an outside so as to be purified, when a process of manufacturing a semiconductor and a flat display is completed, gas containing the large amount of by-products has been generated within the chamber during the process.

In order to exhaust the above-described gas from the chamber, under the control of the controller 30, each vacuum unit 20 included within the main body 10 while having each separate exhaust line is operated. Then, according to the operation of each vacuum unit 20, gas and by-products generated within the chamber is purified by passing through the vacuum pump apparatus 22, the trap 24, and the scrubber 26 via the first exhaust pipe 21, and is exhausted outside.

At this time, non-reacted gas and by-products contained in gas, which has been generated in the chamber and has flowed into the trap 24 through the booster pump 22B of the vacuum pump apparatus 22, undergoes chemical reaction processed by the trap 24, which is manufactured in such a manner that it is optimized so as to correspond to special characteristic of the process, within the trap 24. Therefore, the non-reacting gas and by-products don't flow into the low vacuum pump 22A, and only gas is purified while passing through the scrubber 26 via the low vacuum pump 22A of the vacuum pump apparatus 22 and the second exhaust pipe 25 and is exhausted outside. As a result, non-reacted gas and by-products don't flow into the low vacuum pump 22A and the scrubber 26, so that it is expected that the life span of the vacuum pump apparatus 22 and the scrubber 26 is extended so as to extend the average time interval between trouble occurrences in the low vacuum pump 22A and the scrubber 26.

Also, gas generated within the chamber is purified through each vacuum unit 20 having each separated exhaust line, that is, the vacuum pump apparatus 22, the trap 24, and the scrubber 26, and is exhausted outside, so that it is possible to prevent an excessive operation of the apparatus through distribution of exhausting gas. In a case where the vacuum unit 20 has a trouble or the vacuum pump apparatus 22, the trap 24, and the scrubber 26, which constitute the vacuum unit 20, also have trouble, the exhaust operation can be smoothly achieved through another vacuum unit 20. Therefore, it is possible to resolve a problem that operation of the apparatus is stopped due to inability of exhausting.

Also, in a case where gas generated within the chamber is exhausted through each separate exhaust line so as to be purified, the controller 30 integrally controls the vacuum pump apparatus 22, the trap 24, and the scrubber 26 of the each vacuum unit 20 so that they can easily controlled in operating.

Also, a purifying system has each separate exhaust line, that is, each vacuum unit 20 is included within the main body 10 while corresponding to the chamber so that the installation area of devices constituting the purifying system can be reduced.

1. A process chamber of an apparatus for manufacturing semiconductors, flat panel displays, etc., or exhausts gaseous material and by-products generated within the process chamber to an outside so as to purify them, the integrated vacuum producing apparatus comprising:
a main body;
at least one vacuum pump apparatus received within the main body, the vacuum pump apparatus including a low vacuum pump so as to vacuumize the chamber or exhaust gaseous material and by-products generated within the chamber to an outside, the vacuum pump apparatus being connected with the chamber through a first exhaust pipe;
at least one scrubber connected with the vacuum pump apparatus through a second exhaust pipe, the scrubber being received within the main body so as to purify the gaseous material;
at least one trap connected with the vacuum pump apparatus, the trap causing additional chemical reaction respective to non-reacting gas and by-products contained in gaseous material in the chamber, which flows into the low vacuum pump and the scrubber, so as not to allow them from flowing into the low vacuum pump and the scrubber so that an average time interval between trouble occurrences in the low vacuum apparatus and the scrubber is extended; and
a controller connected with the vacuum pump apparatus, the scrubber, and the trap so as to integrally control them.

2. The integrated vacuum producing apparatus as claimed in claim 1, wherein an exterior of the main body is surrounded by a case.

3. An integrated vacuum producing apparatus, which vacuumizes a process chamber of an apparatus for manufacturing semiconductors, flat panel displays, etc. or exhausts gaseous material and by-products generated within the process chamber to an outside so as to be purified, the integrated vacuum producing apparatus comprising:
a main body; and
at least one vacuum unit which is included in an interior of the main body while corresponding to the chamber and includes a vacuum pump apparatus, a scrubber, and a trap, the vacuum pump apparatus being received within the main body, including a low vacuum pump so as to vacuumize the chamber or exhaust gaseous material and by-products generated within the chamber to an outside, and being connected with the chamber through a first exhaust pipe, the scrubber being connected with the vacuum pump apparatus through a second exhaust pipe so as to purify gaseous material exhausted from the vacuum pump apparatus, the trap being connected with the vacuum pump apparatus, and inducing additional chemical reaction respective to non-reacted gas and by-products contained in the gaseous material in the chamber, which flow into the low vacuum pump and the scrubber, so that the trap prevents them from flowing into the low vacuum pump and the scrubber so as to extend an average time interval between trouble occurrences in the low vacuum apparatus and the scrubber.

4. The integrated vacuum producing apparatus as claimed in claim 3, further comprises a controller for integrally control the vacuum unit.

5. The integrated vacuum producing apparatus as claimed in claim 4, wherein the vacuum unit is surrounded by a case so as to be modulized.

6. The integrated vacuum producing apparatus as claimed in claim 1, wherein the vacuum pump apparatus further includes a booster pump for increasing an exhausting speed of the low vacuum pump.

7. The integrated vacuum producing apparatus as claimed in claim 6, wherein the trap is connected with a front end of the booster pump.

8. The integrated vacuum producing apparatus as claimed in claim 6, wherein the trap is connected between the booster pump and the low vacuum pump.

9. The integrated vacuum producing apparatus as claimed in claim 6, wherein the trap is connected between a front end of the booster pump, the booster pump, and the low vacuum pump.
